(19) United States
(12) Patent Application Publication
(10) Pub. No.: US 2020/0220048 A1
(43) Pub. Date: Jul. 9, 2020

(54) ELECTRICALLY CONDUCTIVE LAYERED STRUCTURE AND METHOD FOR MANUFACTURING THE SAME, AND LIGHT-EMITTING DIODE DEVICE

(71) Applicant: XIAMEN SAN'AN OPTOELECTRONICS CO., LTD., Xiamen (CN)

(72) Inventors: Huining WANG, Xiamen (CN); Sheng-Hsien HSU, Xiamen (CN); Ling-yuan HONG, Xiamen (CN); Kang-Wei PENG, Xiamen (CN); Su-hui LIN, Xiamen (CN); Chen-ke HSU, Xiamen (CN)

(21) Appl. No.: 16/820,509

(22) Filed: Mar. 16, 2020

Related U.S. Application Data
(63) Continuation-in-part of application No. PCT/CN2018/081669, filed on Apr. 3, 2018.

(30) Foreign Application Priority Data
Sep. 18, 2017 (CN) 201710842710.2

(51) Int. Cl. H01L 33/38; H01L 33/42

(52) U.S. Cl. CPC H01L 33/38; H01L 2933/0016; H01L 33/42

(57) ABSTRACT

An electrically conductive layered structure includes a lower transparent conductive layer having a bottom surface, an upper transparent conductive layer formed on the lower transparent conductive layer opposite to the bottom surface, and at least one hole extending from the top surface to the bottom surface. The at least one hole has a first diameter at a first side adjacent to the top surface and a second diameter at a second side opposite to the first side. The first diameter is smaller than the second diameter. A light-emitting diode device including the electrically conductive layered structure and a method for manufacturing the electrically conductive layered structure are also disclosed.

### CROSS-REFERENCE TO RELATED APPLICATION

This application is a bypass continuation-in-part (CIP) application of PCT International Application No. PCT/CN2018/081669, filed on Apr. 3, 2018, which claims priority of Chinese Invention Patent Application No. 201710842710.2, filed on Sep. 18, 2017. The entire content of each of the International and Chinese patent applications is incorporated herein by reference.

### FIELD

This disclosure relates to an electrically conductive layered structure, a light-emitting diode (LED) device including the electrically conductive layered structure, and a method for manufacturing the electrically conductive layered structure.

### BACKGROUND

Group III-V compound semiconductor materials, such as gallium nitride (GaN)-based materials and aluminum gallium indium phosphide (AlGaInP)-based materials, are most commonly used to make light-emitting diode (LED) devices.

In a face-up LED device made from a GaN-based material (i.e., an LED device emitting blue light), an indium tin oxide (ITO) layer may serve not only as a current-spreading layer for improving a light-emitting area of the LED device, but also as a window layer that normally has a relatively high transmittance (i.e., a relatively low absorbance) for blue photons since ITO has a relatively wide band gap (3.6 eV to 3.9 eV). After being annealed in the presence of oxygen at high temperature, transmittance for the visible light of the ITO layer may reach 80% or higher, which indicates that most photons transmit through the ITO layer. It is noted that the LED device with the ITO layer is usually enclosed by an insulating layer made of, e.g., epoxy resin. However, since ITO has a refractive index (1.8 to 2.1) different from that of epoxy resin (1.51 to 1.55), the light reaching the interface between the ITO layer and the epoxy resin layer at a relatively large angle of incidence, e.g., along the light paths “a” and “b” as shown in FIG. 1, may undergo total internal reflection within the ITO layer, which may result in loss thereof due to heat loss, i.e., reduction of light extraction efficiency of the LED device.

Referring to FIG. 2, a conventional method for improving the light-transmittance of the ITO layer is to roughen the upper surface of the ITO layer, e.g., treating with roughening agents. The roughened upper surface might have an increased light-emitting area and might vary an angle of incidence of light to reduce total internal reflection. However, it is difficult to control the degree of roughening of the ITO layer, and the roughening agents might adversely affect the functions of the ITO layer, resulting in worsening of ohmic contact.

### SUMMARY

Therefore, an object of the disclosure is to provide an electrically conductive layered structure, a light-emitting diode (LED) device including the electrically conductive layered structure, and a method for manufacturing the electrically conductive layered structure, that can alleviate at least one of the drawbacks of the prior art.

According to a first aspect of the disclosure, the electrically conductive layered structure includes a lower transparent conductive layer that has a bottom surface for light entrance, an upper transparent conductive layer that is formed on the lower transparent conductive layer opposite to the bottom surface and that has a top surface opposite to the lower transparent conductive layer, and at least one hole that extends from the top surface of the upper transparent conductive layer to the bottom surface of the lower transparent conductive layer. The at least one hole has a first diameter at a first side adjacent to the top surface and a second diameter at a second side opposite to the first side. The first diameter is smaller than the second diameter.

According to a second aspect of the disclosure, the LED device includes an epitaxial layered structure made of a semiconductor material, and the abovementioned electrically conductive layered structure disposed on the epitaxial layered structure.

According to a third aspect of the disclosure, the method for manufacturing the electrically conductive layered structure includes the steps of:

a) providing a lower transparent conductive layer having a bottom surface, and an upper transparent conductive layer disposed on the lower transparent conductive layer opposite to the bottom surface;

b) covering a top surface of the upper transparent conductive layer opposite to the lower transparent conductive layer with a patterned mask, the patterned mask being formed with through-holes; and

c) etching the upper transparent conductive layer and the lower transparent conductive layer in such a manner that a plurality of holes corresponding in positions to the through-holes are formed to extend from the top surface of the upper transparent conductive layer to the bottom surface of the lower transparent conductive layer, each of the holes having a first diameter at a first side adjacent to the top surface and a second diameter at a second side opposite to the first side, the first diameter being smaller than the second diameter.

### BRIEF DESCRIPTION OF THE DRAWINGS

Other features and advantages of the disclosure will become apparent in the following detailed description of the embodiments with reference to the accompanying drawings, of which:

FIG. 1 is a schematic view illustrating light undergoing total internal reflection within a smooth indium tin oxide (ITO) layer of a conventional light-emitting diode (LED) device;

FIG. 2 is a schematic view illustrating light paths in a roughened ITO layer of another conventional LED device;

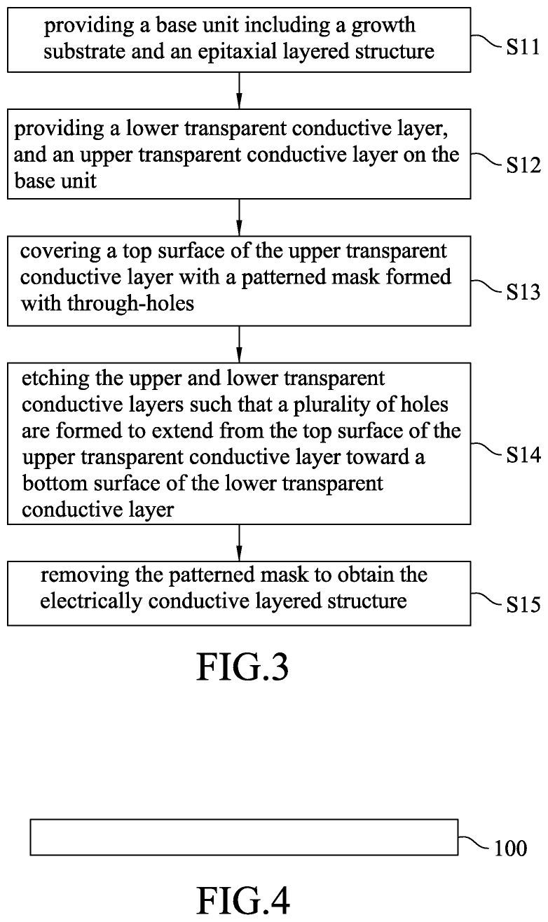

FIG. 3 is a flow chart illustrating a first embodiment of a method for manufacturing a first embodiment of an electrically conductive layered structure according to the disclosure;

FIGS. 4 to 9 are schematic views illustrating consecutive steps of the method of FIG. 3, in which FIG. 7 is a top view of FIG. 6; and

FIG. 10 is a schematic view illustrating a patterned mask having a multi-layered structure used in a second embodiment of the method according to the disclosure.

### DETAILED DESCRIPTION

Before the disclosure is described in greater detail, it should be noted that where considered appropriate, reference numerals have been repeated among the figures to indicate corresponding or analogous elements, which may optionally have similar characteristics.

Referring to FIG. 9, a first embodiment of an electrically conductive layered structure includes a lower transparent conductive layer 200, an upper transparent conductive layer 201, and at least one hole 202.

The lower transparent conductive layer 200 is formed on the epitaxial layered structure of a base unit 100, and has a bottom surface facing the base unit 100. The lower transparent conductive layer 200 may have a thickness ranging from 50 Å to 200 Å.

The upper transparent conductive layer 201 is formed on the lower transparent conductive layer 200 opposite to the bottom surface 2001, and has a top surface 2011 opposite to the lower transparent conductive layer 200. The upper transparent conductive layer 201 may have a thickness greater than that of the lower transparent conductive layer 200. For example, the upper transparent conductive layer 201 may have a thickness ranging from 400 Å to 2000 Å.

The lower transparent conductive layer 200 and the upper transparent conductive layer 201 are independently made of a material selected from the group consisting of indium tin oxide (ITO), zinc oxide (ZnO), cadmium tin oxide (CTO), indium oxide (InO), indium-doped zinc oxide (InZnO), aluminum-doped zinc oxide (AlZnO), gallium-doped zinc oxide (GaZnO), and combinations thereof. The lower transparent conductive layer 200 has an etch rate by an etchant higher than that of the upper transparent conductive layer 201. It is noted that, under an acidic etching solution, among the abovementioned materials, InO has the lowest etch rate, ITO has an etch rate higher than that of InO, and the remaining materials (including CTO, ZnO, and other doped ZnO) have even higher etch rates than ITO. In this embodiment, the lower transparent conductive layer 200 is made of ZnO, and the upper transparent conductive layer 201 is made of ITO.

The at least one hole 202 extends from the top surface 2011 of the upper transparent conductive layer 201 to the bottom surface 2001 of the lower transparent conductive layer 200. That is, the at least one hole 202 penetrate the lower and upper transparent conductive layers 200, 201 to form through-holes. The at least one hole 202 has a first diameter at a first side adjacent to the top surface 2011 and a second diameter at a second side opposite to the first side. The first diameter is smaller than the second diameter.

In certain embodiments, the at least one hole 202 is gradually enlarged from the first side to the second side. In other embodiments, a cross-section of the at least one hole 202 along a plane perpendicular to the top surface 2011 of the upper transparent conductive layer 201 has a substantially trapezoidal shape. As used herein, the term “substantially trapezoidal” may refer to any shape having four major sides with two of the major sides being parallel to one another, but with some variation in the shape of the segments and/or the number of minor sides.

The hole 202 may have a size in the nanoscale range. In this embodiment, the electrically conductive structure includes a plurality of the holes 202 that are spaced-apart from one another. The arrangement of the holes 202 is not particularly limited and may be varied according to practical requirements. In this embodiment, the holes are periodically arranged. A cross-section of the combined lower and upper transparent conductive layers 200, 201 along the plane perpendicular to the top surface 2011 of the upper transparent conductive layer 201 may be substantially inverted trapezoidal in shape.

The electrically conductive layered structure may be provided on a base unit 100, and a metallic electrode layer (not shown) may be further formed on the electrically conductive layered structure to obtain a light-emitting diode (LED) device.

The base unit 100 may be one of a growth substrate, an epitaxial layered structure, and the combination thereof. In this embodiment, the base unit 100 includes a growth substrate and an epitaxial layered structure formed on the growth substrate. The growth substrate may be made of a material selected from sapphire, silicon carbide, silicon, gallium nitride (GaN), zinc oxide, and combinations thereof. The epitaxial layered structure maybe made of a GaN-based material, a gallium phosphide (GaP)-based material, a gallium nitride phosphide (GaNP)-based material, or a zinc oxide-based material. In this embodiment, the epitaxial layered structure is made of a GaN-based material, and includes a first-type cladding layer, an active layer disposed on the first-type cladding layer, and a second-type cladding layer disposed on the active layer. The first-type cladding layer is an N-type cladding layer made of GaN, and the second-type cladding layer is a P-type cladding layer made of aluminum gallium nitride (AlGaN). The active layer is made of AlGaN, and includes multiple quantum wells. It should be noted that the configuration and composition of the epitaxial layered structure, which are well-known to those skilled in the art, may be varied according to practical requirements and should not be not limited to the embodiments disclosed herein. For example, the active layer may include indium gallium nitride (InGaN)/GaN multiple quantum wells, and the second-type cladding layer may be a P-type cladding layer made of GaN. In addition, the epitaxial layered structure may further include a buffer layer disposed between the first-type cladding layer and the growth substrate.

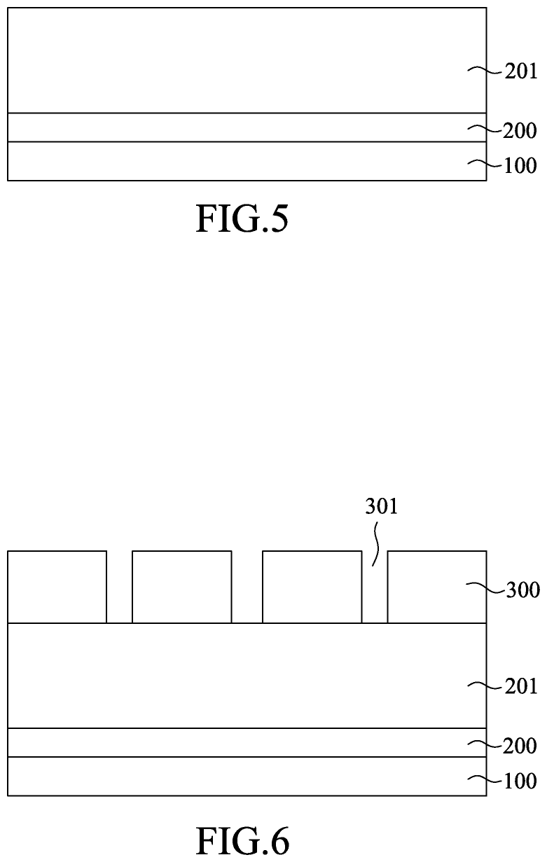

Referring to FIG. 3, a first embodiment of a method for manufacturing the first embodiment of the electrically conductive layered structure as shown in FIG. 9 includes the following steps S11 to S15.

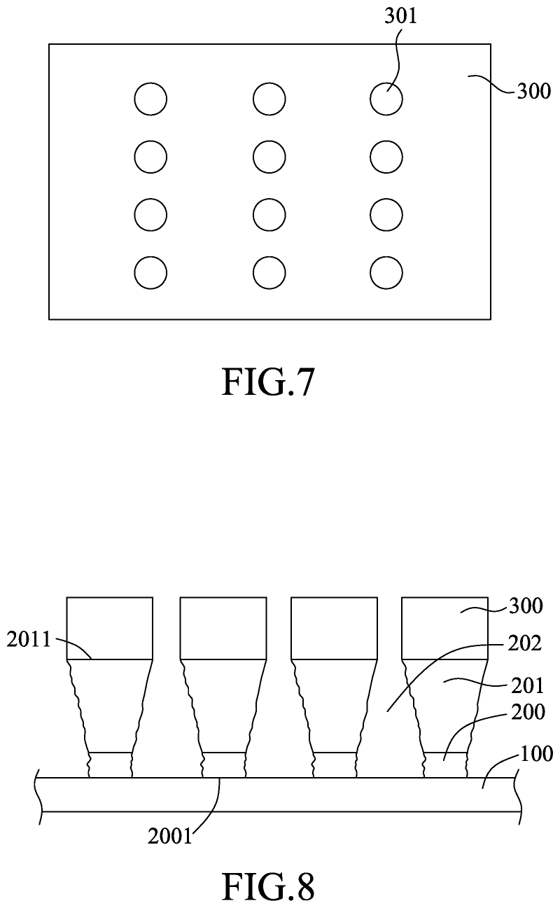

Referring to FIG. 4, in step S11, the base unit 100 including the growth substrate and the epitaxial layered structure is provided. In this embodiment, the epitaxial layered structure is grown on the growth substrate using a metal organic chemical vapor phase deposition (MOCVD) process.

Referring to FIG. 5, in step S12, the lower transparent conductive layer 200 having the bottom surface 2001, and the upper transparent conductive layer 201 disposed on the lower transparent conductive layer 200 opposite to the bottom surface 2001 are provided on the base unit 100.

To be specific, the lower and upper transparent conductive layers 200, 201 are sequentially formed on the epitaxial layered structure of the base unit 100 using, e.g., a sputtering process, an evaporation process, a plasma-enhanced chemical vapor deposition (PECVD), or combinations thereof. The sputtering process may include a magnetron sputtering process and a radio frequency (RF) sputtering process. The evaporation process may include a vacuum evaporation process and an electron beam evaporation process. The upper and lower transparent conductive layers 201, 200 may be formed by different processes as mentioned. Alternatively, the upper and lower transparent conductive layers 201, 200 may be formed by a same process such as multi-target magnetron sputtering, in which different targets may be used in a sputtering machine to form layers of different materials such as ITO, ZnO, or other doped materials. In this embodiment, the lower transparent conductive layer 200 made of ZnO is formed by the magnetron sputtering process, and the upper transparent conductive layer 201 made of ITO is formed by the same process. Afterwards, the upper and lower transparent conductive layers 201, 200 are subjected to an annealing process under an annealing temperature ranging from 500° C. to 650° C., and are maintained at the annealing temperature for 3 to 5 minutes in the presence of an oxygen flux ranging from 15 sccm to 30 sccm.

Referring to FIGS. 6 and 7, in step S13), the patterned mask 300, which is formed with through-holes 301, covers the top surface 2011 of the upper transparent conductive layer 201 opposite to the lower transparent conductive layer 200. In this embodiment, the patterned mask 300 has a single-layer structure, and is patterned using a photolithography process to form the through-holes 301 which have sizes in the nanoscale range, and which are arranged periodically.

Referring to FIG. 8, in step S14, the upper and lower transparent conductive layers 201, 200 are etched in such a manner that a plurality of the holes 202 corresponding in position to the through-holes 301 are formed to extend from the top surface 2011 of the upper transparent conductive layer 201 to the bottom surface 2001 of the lower transparent conductive layer 200. The etching may be performed using one of a dry etching process, a wet etching process, and the combination thereof.

In this embodiment, a wet etching process is performed by using an acidic solution such as a dilute sulfuric acid solution or a dilute hydrochloric acid solution having a concentration ranging from 5% to 10% for an etching period ranging from 1 minute to 5 minutes. Since ZnO has an etch rate higher than that of ITO, the lower transparent conductive layer 200 is etched at an etch rate higher than that of the upper transparent conductive layer 201. Therefore, each of the holes 202 has a cross-section along the plane perpendicular to the top surface 2011 of the upper transparent conductive layer 201 in a substantially trapezoidal shape. It should be noted that the materials of the upper and lower transparent conductive layers 201, 200 may be selected depending on the degree of inclination of the holes 202 to be formed.

Referring to FIG. 9, in step S15, the patterned mask 300 is removed to obtain the electrically conductive layered structure. The metallic electrode layer (not shown) maybe formed on the upper transparent conductive layer 201 to obtain the LED device that includes the first embodiment of the electrically conductive layered structure.

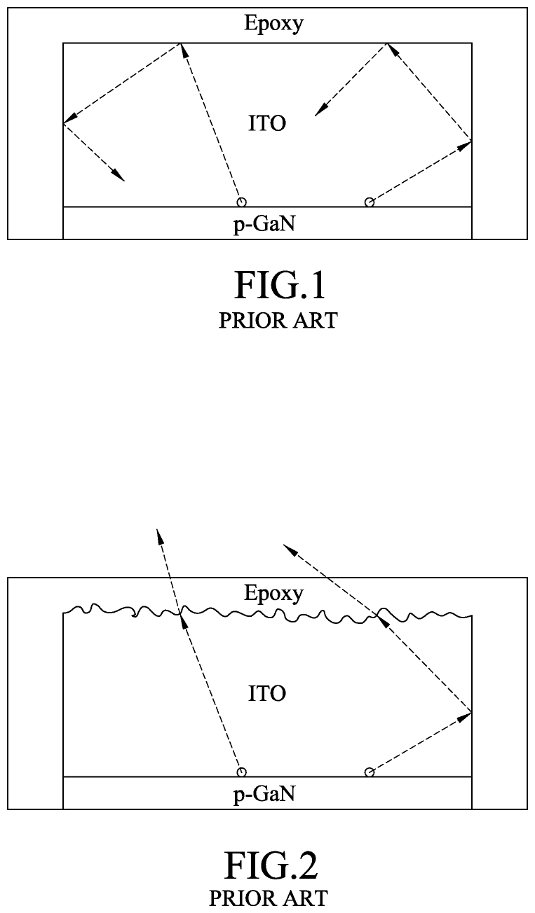

In comparison with the light paths “a” and “b” shown in FIG. 1, FIG. 9 shows that the electrically conductive layered structure of this disclosure, which has several inclined side surfaces by virtue of the formation of the holes 202, may facilitate light emitted from the epitaxial layered structure to transmit therethrough without undergoing total internal reflection within the LED device, thereby improving a light extraction efficiency of the LED device.

It should be noted that, in the method for manufacturing the electrically conductive layered structure of this disclosure, the annealing process is not limited to be performed after step S12, and may be performed after step S15, as long as an ohmic contact can be formed between the upper and lower transparent conductive layer 201, 200.

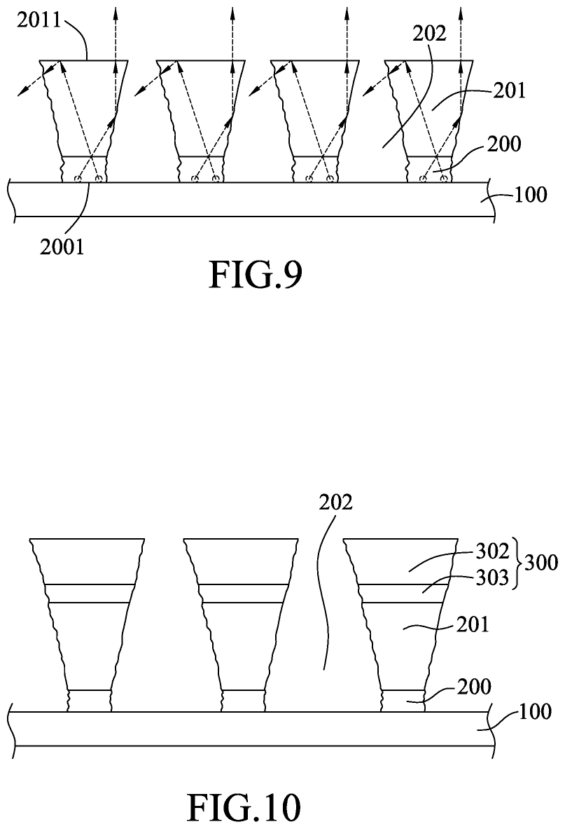

Referring to FIG. 10, a second embodiment of the method is conducted similarly to the first embodiment except that the patterned mask 300 used in step S13 has a multi-layered structure. In this embodiment, the patterned mask 300 includes an upper mask layer 302 and a lower mask layer 303. The upper mask layer 302 is made of silicon oxide (SiO₂), and the lower mask layer 303 is made of silicon nitride (SiN), which has an etched rate higher than that of SiO₂. The upper mask layer 302 and the lower mask layer 303 are subjected to wet etching using a buffered oxide etch (BOE) solution such that the pattered mask 300 has a cross-section along the plane perpendicular to the top surface 2011 of the upper transparent conductive layer 201 in a substantially inverted trapezoidal shape. That is, each of the through holes 301 of the patterned mask 300 has a diameter that gradually increases from the upper mask layer 302 to the lower mask layer 303. In addition, in this embodiment, dry etching is performed in step S14.

A third embodiment of the method is conducted similarly to the first embodiment of the method except that both the upper and lower transparent conductive layers 201, 200 formed in step S12 are made of an ITO material, but with a different ratio of indium (In) to tin (Sn). To be specific, the ratio of In to Sn in the lower transparent conductive layer 200 is larger than that of the upper transparent conductive layer 201 since an ITO material having a relatively high amount of In may have an etch rate higher than that having a relatively low amount of In. For example, the lower transparent conductive layer 200 may be made of an ITO material having an In:Sn ratio of 95:5, and the upper transparent conductive layer 201 may be made of an ITO material having an In:Sn ratio of 90:10.

In sum, by formation of the hole 202, which has a larger diameter near the lower transparent conductive layer 200 and a smaller diameter near the upper transparent conductive layer 201, the electrically conductive layered structure of the disclosure may have an improved light transmittance and a reduced total internal refection therewithin, so that the LED device including the electrically conductive layered structure may have an improved light extraction efficiency.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. An electrically conductive layered structure for transmitting light, comprising:
a lower transparent conductive layer having a bottom surface for light entry;
an upper transparent conductive layer formed on said lower transparent conductive layer opposite to said bottom surface and having a top surface opposite to said lower transparent conductive layer; and
at least one hole that extends from said top surface of said upper transparent conductive layer to said bottom surface of said lower transparent conductive layer, and that has a first diameter at a first side adjacent to said top surface and a second diameter at a second side opposite to said first side, said first diameter being smaller than said second diameter.

2. The electrically conductive layered structure according to claim 1, wherein said at least one hole is gradually enlarged from said first side to said second side.

3. The electrically conductive layered structure according to claim 1, wherein said electrically conductive layered structure includes a plurality of said holes that are spaced-apart from one another.

4. The electrically conductive layered structure according to claim 3, wherein said holes are periodically arranged.

5. The electrically conductive layered structure according to claim 1, wherein said at least one hole has a size in the nanoscale range.

6. The electrically conductive layered structure according to claim 1, wherein a cross-section of said at least one hole along a plane perpendicular to said top surface of said upper transparent conductive layer has a substantially trapezoidal shape.

7. The electrically conductive layered structure according to claim 1, wherein said upper transparent conductive layer has a thickness greater than that of said lower transparent conductive layer.

8. The electrically conductive layered structure according to claim 1, wherein said lower transparent conductive layer and said upper transparent conductive layer are independently made of a material selected from the group consisting of indium tin oxide (ITO), zinc oxide (ZnO), cadmium tin oxide (CTO), indium oxide (InO), indium-doped zinc oxide (InZnO), aluminum-doped zinc oxide (AlZnO), gallium-doped zinc oxide (GaZnO), and combinations thereof.

9. The electrically conductive layered structure according to claim 8, wherein said lower transparent conductive layer has an etch rate by an etchant higher than that of said upper transparent conductive layer.

10. A light-emitting diode device, comprising:
an epitaxial layered structure made of a semiconductor material; and
an electrically conductive layered structure of claim 1 disposed on said epitaxial layered structure.

11. A method for manufacturing an electrically conductive layered structure for transmitting light, including the steps of:
a) providing a lower transparent conductive layer having a bottom surface, and an upper transparent conductive layer disposed on the lower transparent conductive layer opposite to the bottom surface;
b) covering a top surface of the upper transparent conductive layer opposite to the lower transparent conductive layer with a patterned mask, the patterned mask being formed with through-holes; and
c) etching the upper transparent conductive layer and the lower transparent conductive layer in such a manner that a plurality of holes corresponding in positions to the through-holes are formed to extend from the top surface of the upper transparent conductive layer to the bottom surface of the lower transparent conductive layer, each of the holes having a first diameter at a first side adjacent to the top surface and a second diameter at a second side opposite to the first side, the first diameter being smaller than the second diameter.

12. The method according to claim 11, wherein in step c), the lower transparent conductive layer is etched at an etch rate that is higher than that of the upper transparent conductive layer.

13. The method according to claim 11, wherein in step a), the lower transparent conductive layer is provided on a base unit, the bottom surface facing the base unit.

14. The method according to claim 14, wherein the base unit includes one of a growth substrate, an epitaxial layered structure, and the combination thereof.

15. The method according to claim 11, wherein in step a), the lower transparent conductive layer and the upper transparent conductive layer are formed by a process selected from the group consisting of an evaporation process, a sputtering process, and the combination thereof.

16. The method according to claim 11, wherein step c) is performed using a process selected from the group consisting of a dry etching process, a wet etching process, and the combination thereof.

17. The method according to claim 11, wherein in step c), the patterned mask has a single-layer structure.

18. The method according to claim 11, wherein in step c), the patterned mask has a multi-layered structure.

19. The method according to claim 11, wherein the upper transparent conductive layer and the lower transparent conductive layer are independently made of a material selected from the group consisting of indium tin oxide (ITO), zinc oxide (ZnO), cadmium tin oxide (CTO), indium oxide (InO), In-doped zinc oxide (InZnO), aluminum-doped zinc oxide (AlZnO), gallium-doped zinc oxide (GaZnO), and combinations thereof.
